(19) United States
(12) Patent Application Publication
(10) Pub. No.: US 2025/0254960 A1
(43) Pub. Date: Aug. 7, 2025

(54) SEMICONDUCTOR DEVICE

(71) Applicant: FUJI ELECTRIC CO., LTD., Kanagawa (JP)

(72) Inventor: Kenichi ISHII, Matsumoto-city (JP)

(21) Appl. No.: 19/001,328

(22) Filed: Dec. 24, 2024

(30) Foreign Application Priority Data
Feb. 6, 2024 (JP) 2024-016710

(51) Int. Cl. H10D 64/23; H01L 23/31; H01L 23/528; H10D 12/00; H10D 64/64

(52) U.S. Cl. CPC H10D 64/232; H01L 23/3171; H01L 23/5283; H10D 12/481; H10D 64/64

(57) ABSTRACT

A semiconductor device including: an interlayer dielectric film provided between an upper surface of a semiconductor substrate and an upper surface electrode and having a first contact hole connecting the semiconductor substrate and the upper surface electrode; a protection film provided on an upper surface of the upper surface electrode; and a plating layer provided on a region, which is not covered with the protection film, of the upper surface of the upper surface electrode, wherein the semiconductor substrate has a first end side in a top view, the first contact hole includes a first outer hole end portion closest to the first end side, and the plating layer is formed on a portion, which overlaps with the first outer hole end portion, of the upper surface electrode.

The contents of the following patent application are incorporated herein by reference:
NO. 2024-016710 filed in JP on Feb. 6, 2024

### BACKGROUND

### 1. Technical Field

The present invention relates to a semiconductor device.

### 2. Related Art

Conventionally, a semiconductor device has been known which is provided with a protection film such as polyimide covering an emitter electrode (for example, see Patent Document 1).
Patent Document 1: Japanese Patent Application Publication No. 2022-059487

### BRIEF DESCRIPTION OF THE DRAWINGS

FIG. 1 is a top view showing one example of a semiconductor device 100 according to one embodiment of the present invention.

FIG. 2 is an enlarged view of a region A in FIG. 1.

FIG. 3 shows one example of a cross section X1-X1′ in FIG. 2.

FIG. 4 shows one example of a cross section Y1-Y1′ in FIG. 2.

FIG. 5 shows one example of a cross section Y2-Y2′.

FIG. 6 shows another example of a cross section Y2-Y2′.

FIG. 7 illustrates a path of an electron hole current from an outer hole end portion 281 in a comparative example.

FIG. 8 illustrates a path of an electron hole current from an outer hole end portion 281 in an embodiment example.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are essential to the solution of the invention.

In the present specification, one side in a direction parallel to a depth direction of a semiconductor substrate is referred to as “upper” and another side is referred to as “lower”. One surface of two principal surfaces of a substrate, a layer or another member is referred to as an upper surface, and another surface is referred to as a lower surface. “Upper” and “lower” directions are not limited to a direction of gravity, or a direction in which a semiconductor device is mounted.

In the present specification, technical matters may be described using orthogonal coordinate axes of the X axis, the Y axis, and the Z axis. The orthogonal coordinate axes merely specify relative positions of components, and do not limit a specific direction. For example, the Z axis is not limited to indicate the height direction with respect to the ground. It is to be noted that the +Z axis direction and the −Z axis direction are directions opposite to each other. When the Z axis direction is described without describing the signs, it means that the direction is parallel to the +Z axis and the −Z axis.

In the present specification, orthogonal axes parallel to the upper surface and the lower surface of the semiconductor substrate are referred to as the X axis and the Y axis. In addition, an axis perpendicular to the upper surface and the lower surface of the semiconductor substrate is referred to as the Z axis. In the present specification, the direction of the Z axis may be referred to as the depth direction. In addition, in the present specification, a direction parallel to the upper surface and the lower surface of the semiconductor substrate may be referred to as a horizontal direction, including the X axis direction and the Y axis direction.

A region from the center of the semiconductor substrate in the depth direction to the upper surface of the semiconductor substrate may be referred to as a side of the upper surface. Similarly, a region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of doping region doped with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type or a semiconductor presenting a conductivity type of the P type.

In the present specification, a description of a P+ type or an N+ type means a higher doping concentration than that of the P type or the N type, and a description of a P-type or an N-type means a lower doping concentration than that of the P type or the N type. In addition, in the present specification, a description of a P++ type or an N++ type means a higher doping concentration than that of the P+ type or the N+ type.

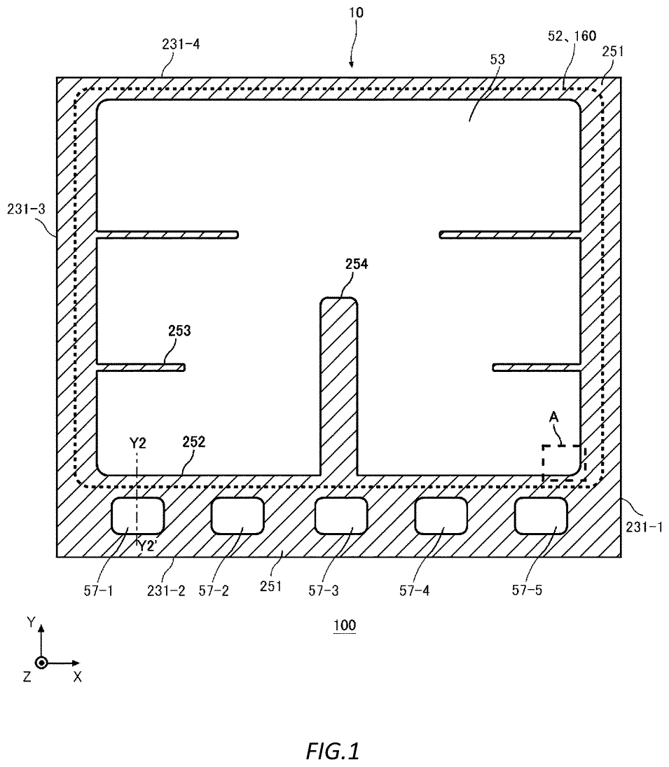

FIG. 1 is a top view showing one example of a semiconductor device 100 according to one embodiment of the present invention. FIG. 1 shows a position of each member projected onto an upper surface of a semiconductor substrate 10. FIG. 1 shows the semiconductor substrate 10, an upper surface electrode 52, an active portion 160, a protection film 251, a protection film 252, a protection film 253, and a protection film 254 of the semiconductor device 100, and omits another member. The protection film 251, the protection film 252, the protection film 253, and the protection film 254 may each be a dielectric film formed of a polymer compound such as polyimide.

The semiconductor device 100 includes the semiconductor substrate 10. The semiconductor substrate 10 is a substrate formed of a semiconductor material. As one example, the semiconductor substrate 10 is a silicon substrate, but may be a compound semiconductor substrate formed of silicon carbide, gallium nitride, gallium arsenide, or the like.

In the present specification, a phrase “top view” refers to a view from a side of the upper surface of the semiconductor substrate 10. The semiconductor substrate 10 in the present example has a plurality of end sides 231 in a top view. In FIG. 1, the X axis and the Y axis are parallel to any end side 231. In addition, the Z axis is perpendicular to the upper surface of the semiconductor substrate 10.

The semiconductor substrate 10 in the present example may have two sets of end sides opposite to each other (in FIG. 1, a set of end sides 231-1 and 231-3, and a set of end sides 231-2 and 231-4). In the present specification, each end side 231 may be referred to as a first end side, a second end side, a third end side, or a fourth end side. Any end side 231 may serve as the first end side. Any end side 231 may serve as the second end side, the third end side, or the fourth end side.

Some figures in the present specification describe a cross sectional structure in a vicinity of any end side 231. A structure in a vicinity of another end side 231 opposite to the end side 231 may be similar to that in the vicinity of the end side 231. For example, a structure in a vicinity of the end side 231-1 may be similar to that in a vicinity of the end side 231-3. A structure in a vicinity of the end side 231-2 may be similar to that in a vicinity of the end side 231-4. It should be noted that a pad 57 and the protection film 252 are not provided in the vicinity of the end side 231-4.

The upper surface electrode 52 is provided above the upper surface of the semiconductor substrate 10. In FIG. 1, a region provided with the upper surface electrode 52 is enclosed by a dotted line. The upper surface electrode 52 is an electrode through which a main current of a semiconductor element provided in the semiconductor substrate 10 flows. If the semiconductor element is an insulated gate bipolar transistor (IGBT), the upper surface electrode 52 may be an emitter electrode. If the semiconductor element is a MOSFET, the upper surface electrode 52 may be a source electrode. If the semiconductor element is a diode, the upper surface electrode 52 may be an anode electrode.

The upper surface electrode 52 is formed of metal. At least a partial region of the upper surface electrode 52 may be formed of aluminum or an aluminum-silicon alloy. The upper surface electrode 52 may have a barrier metal formed of titanium, a titanium compound, or the like, at a layer underlying a region formed of aluminum or the like. Further, a contact hole may have therein a plug formed by embedding tungsten or the like so as to contact the barrier metal and aluminum or the like.

The semiconductor substrate 10 is provided with the active portion 160 in which a semiconductor element is formed. As described above, the semiconductor element may include at least one of an IGBT, a MOSFET, or a diode. The present specification describes an example in which the semiconductor substrate 10 is provided with an IGBT. The semiconductor substrate 10 may have a reverse conduction IGBT (RC-IGBT), or may have a reverse blocking IGBT (RB-IGBT). In addition, if the semiconductor substrate 10 is provided with a MOSFET, an “emitter” and a “collector” described in the present specification may be respectively replaced by a “source” and a “drain”.

The active portion 160 is a region through which the main current flows in a depth direction between the upper surface and a lower surface of the semiconductor substrate 10 if the semiconductor element operates. The active portion 160 in the present example refers to a region enclosed by a well region 11, which will be described later, in a top view. The upper surface electrode 52 is provided above the active portion 160. In FIG. 1, the active portion 160 and the upper surface electrode 52 share a common range, but a range of the active portion 160 may be different from a range of the upper surface electrode 52.

The semiconductor device 100 may have one or more pads 57 above the semiconductor substrate 10. The one or more pads 57 may include a pad insulated from the upper surface electrode 52, or may include a pad connected to the upper surface electrode 52. The one or more pads 57 include a gate pad connected to a gate electrode of an IGBT or a MOSFET, for example. The one or more pads 57 may have a pad for detecting temperature, a pad for detecting current, a pad for detecting potential in the upper surface electrode 52, or the like. Each pad 57 in the present example is arranged in the vicinity of the end side 231-2. The vicinity of the end side 231-2 refers to a region between the end side 231-2 and the upper surface electrode 52 or the active portion 160 in a top view. When the semiconductor device 100 is mounted, the upper surface electrode 52 and the pads 57 may be connected to an external circuit via a wiring such as a wire.

At least one portion of each of the protection film 251, the protection film 252, the protection film 253, and the protection film 254 is arranged above the upper surface electrode 52 or the pads 57. In FIG. 1, a region in which each protection film is formed is hatched with diagonal lines. Each protection film exposes at least part of an upper surface 53 of the upper surface electrode 52. A wiring such as a wire may be connected to the exposed part of the upper surface 53. In addition, each protection film exposes at least part of an upper surface of each pad 57. A wiring such as a wire may also be connected to the upper surface of each pad 57.

The protection film 251 is provided in contact with the end sides 231 in a top view. The protection film 251 in the present example is annularly provided along the end sides 231 of the semiconductor substrate 10. The protection film 251 may be provided extending from each end side 231 to a position overlapping with the upper surface electrode 52 or to positions overlapping with the pads 57. The protection film 251 in the present example extends from each of the end sides 231-1, 231-3, and 231-4 to the position overlapping with the upper surface electrode 52. In addition, the protection film 251 extends from the end side 231-2 to the positions overlapping with the pads 57.

The protection film 252 is provided extending from the pads 57 to the upper surface electrode 52 in a top view. The protection film 252 is connected to the protection film 251. The protection film 251 may be provided between two pads 57. In a top view, a partial region of the upper surface 53 of the upper surface electrode 52 is enclosed by the protection film 251 and the protection film 252. In addition, in a top view, a partial region of the upper surface of each pad is enclosed by the protection film 251 and the protection film 252.

The protection film 253 is provided extending inward in the active portion 160 from an end portion of the protection film 251. A phrase “inward in the active portion 160” refers to a direction toward a center of the active portion 160 in a top view. The protection film 253 may overlap with a gate runner arranged in the active portion 160. The gate runner is a wiring for transmitting a gate voltage. The gate runner may include a metal wiring formed of metal such as aluminum, may include a semiconductor wiring formed of a semiconductor such as polysilicon to which an impurity is added, or may be a laminate of a metal wiring and a semiconductor wiring.

The gate runner may have: an annular portion arranged outside the upper surface electrode 52 in a top view; and an inward portion extending inward in the active portion 160 from the annular portion. The annular portion of the gate runner is connected to a gate pad (for example, a pad 57-3). The annular portion of the gate runner may be arranged below the protection film 251 or the protection film 252. The annular portion and the inward portion of the gate runner are connected to a gate electrode of the semiconductor element provided in the active portion 160. Such a structure allows application of a gate voltage to a gate electrode at each position on the semiconductor substrate 10.

The protection film 254 is provided extending inward in the active portion 160 from an end portion of the protection film 251 or the protection film 252. The protection film 254 may overlap with a diode for detecting temperature arranged above the active portion 160 and with a wiring connected to the diode. The diode for detecting temperature is a PN junction diode formed of polysilicon, for example.

The well region 11, which will be described later, may be formed in the semiconductor substrate 10 below each protection film. The well region 11 is a region of a P+ type exposed on the upper surface of the semiconductor substrate 10. The well region 11 may have a higher doping concentration than a base region 14 which will be described later. The well region 11 may be formed to a greater depth than the base region 14.

The semiconductor substrate 10 may include an edge termination structure portion between the well region 11 and the end sides 231. The edge termination structure portion reduces electric field strength on the side of the upper surface of the semiconductor substrate 10. The edge termination structure portion may include at least one of a guard ring, a field plate, or a RESURF annularly provided enclosing the active portion 160.

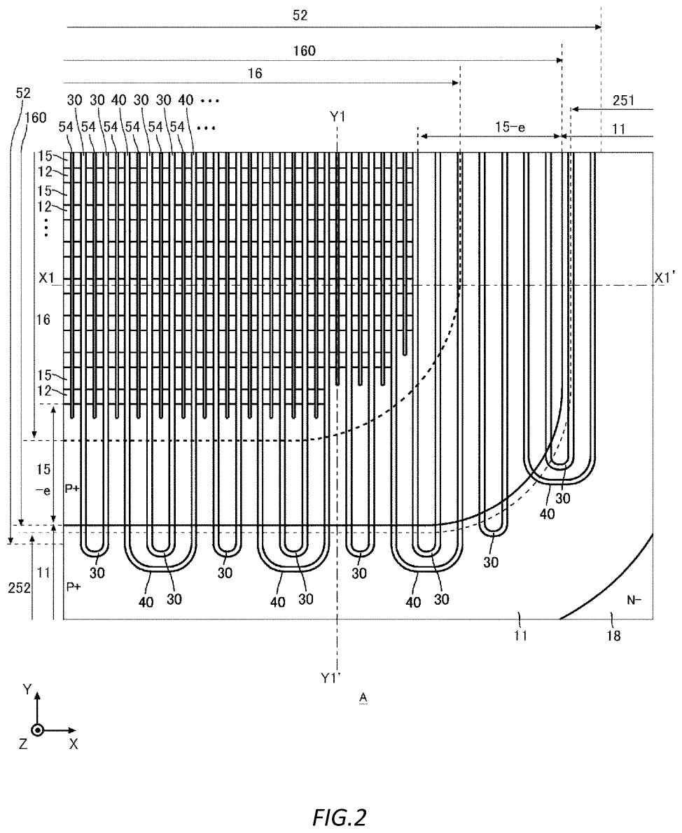

FIG. 2 is an enlarged view of a region A in FIG. 1. The region A is a region including the upper surface electrode 52, the active portion 160, the well region 11, the protection film 251, and the protection film 252. The upper surface electrode 52 in the present example is provided in a wider range than the active portion 160. An interlayer dielectric film is provided between the semiconductor substrate 10 and the upper surface electrode 52, but is omitted in FIG. 2. The interlayer dielectric film is provided with a first contact hole 54 electrically connecting the semiconductor substrate 10 and the upper surface electrode 52.

FIG. 2 indicates, by solid lines, each region such as the well region 11 provided inside the semiconductor substrate 10 and exposed on the upper surface of the semiconductor substrate 10. In addition, it indicates the first contact hole 54 by a solid line. It indicates, by a broken line and arrows, a range provided with an accumulation region 16 which is provided inside the semiconductor substrate 10 and is not exposed on the upper surface of the semiconductor substrate 10. In addition, it indicates, by broken lines and arrows, ranges provided with the upper surface electrode 52, the active portion 160, the protection film 251, and the protection film 252.

The well region 11 is provided so as to enclose the active portion 160 and the upper surface electrode 52. One portion of the well region 11 may overlap with the upper surface electrode 52. The gate runner described above is provided above the well region 11, but is omitted in FIG. 2. The gate runner is arranged farther outward than the upper surface electrode 52 in a top view. A phrase “outward” refers to a side closer to the end sides 231 of the semiconductor substrate 10. The gate runner may be provided in a range overlapping with the well region 11 in a top view. The well region 11 may be provided in a wider range than the gate runner. A drift region 18 of an N-type may be exposed on the upper surface of the semiconductor substrate 10 outside the well region 11.

The protection film 251 and the protection film 252 are arranged farther outward than the active portion 160 in a top view. Part of the protection film 251 overlaps with the upper surface electrode 52 in a top view. In the example shown in FIG. 2, an inner end portion of the protection film 251 in the X axis direction is arranged above the upper surface electrode 52. A term “inner” refers to a side farther from the end sides 231 of the semiconductor substrate 10 (that is, a side closer to the center of the active portion 160). Part of the protection film 252 overlaps with the upper surface electrode 52 in a top view. In the example shown in FIG. 2, an inner end portion of the protection film 252 in the Y axis direction is arranged above the upper surface electrode 52.

An IGBT is formed as a semiconductor element in the active portion 160 in the present example. The active portion 160 in FIG. 2 is provided with a gate trench portion 40, a dummy trench portion 30, an emitter region 12, a contact region 15, and the accumulation region 16.

The gate trench portion 40 and the dummy trench portion 30 are each one example of a trench portion. Each trench portion has: a groove portion provided in the upper surface of the semiconductor substrate 10; a conductive portion provided inside the groove portion; and a dielectric film insulating the semiconductor substrate 10 from the conductive portion. A gate voltage is applied to the conductive portion of the gate trench portion 40, and a voltage different from the gate voltage is applied to the conductive portion of the dummy trench portion 30. The conductive portion of the dummy trench portion 30 in the present example is connected to the upper surface electrode 52 through a contact hole provided in the interlayer dielectric film, or the like.

Each trench portion is provided from the upper surface of the semiconductor substrate 10 into the semiconductor substrate 10. As shown in FIG. 2, each trench portion has a longitudinal length extending in the Y axis direction (a first direction) on an upper surface 21 of the semiconductor substrate 10, and respective trench portions are arranged side by side in a second direction (the X axis direction) different from the Y axis direction. In the present example, the first direction and the second direction are orthogonal to each other, but the first direction and the second direction may not be orthogonal to each other.

In the X axis direction, one or more dummy trench portions 30 are provided between two gate trench portions 40. In the example shown in FIG. 2, one gate trench portion 40 and two dummy trench portions 30 are repeatedly provided in the X axis direction. In another example, a larger number of gate trench portions 40 may be continuously arranged in the X axis direction, or a larger number of dummy trench portions 30 may be continuously arranged in the X axis direction. In addition, the active portion 160 may not be provided with dummy trench portions 30, and may have only gate trench portions 40 arranged therein.

As shown in FIG. 2, end portions of two gate trench portions 40 in the Y axis direction may be connected by a curved gate trench portion 40. Similarly, end portions of two dummy trench portions 30 in the Y axis direction may be connected by a curved dummy trench portion 30. Such a shape can reduce electric field strength at an edge of the trench portion in the Y axis direction. In the present specification, a linear portion extending in the Y axis direction in each trench portion may be considered as one trench portion.

The gate trench portion 40 is electrically connected to the gate runner described above. The gate trench portion 40 extends into the well region 11 in the Y axis direction. The dummy trench portion 30 may also extend into the well region 11. An end portion of the gate trench portion 40 is electrically connected to the gate runner provided above the well region 11. An edge portion of the gate trench portion 40 may be connected to the gate runner through a contact hole provided in the interlayer dielectric film, or the like.

The well region 11 may be formed to a greater depth than each trench portion. With such a configuration, an edge of each trench portion in the Y axis direction is enclosed by the well region 11 of a P+ type. Therefore, it is possible to reduce electric field strength at the edge of each trench portion and improve a breakdown voltage.

In the X axis direction, a mesa portion is provided between the respective trench portions. The mesa portion refers to a region sandwiched between two trench portions adjacent to each other in the X axis direction inside the semiconductor substrate 10. One mesa portion is arranged between every two trench portions. As one example, an upper end of the mesa portion is the upper surface of the semiconductor substrate 10. A depth position of a lower end of the mesa portion is the same as a depth position of a lower end of the trench portion. The mesa portion in the present example is provided extending in the Y axis direction along a trench on the upper surface of the semiconductor substrate 10. Each mesa portion may be connected to the upper surface electrode 52 through the first contact hole 54.

A base region of a P type is provided in each mesa portion, but is omitted in FIG. 2. The base region has a portion provided in contact with the gate trench portion 40. When a predetermined gate voltage is applied to the gate trench portion 40, a channel is formed in the base region, and the IGBT is turned on. The base region may be provided over an entirety of the mesa portion inside the semiconductor substrate 10. The base region may be or may not be exposed on an upper surface of the mesa portion.

Each mesa portion has the emitter region 12 in contact with the upper surface (in other words, exposed on the upper surface) of the semiconductor substrate 10. The emitter region 12 is provided between the base region and the upper surface of the semiconductor substrate 10. At least part of the emitter regions 12 is provided in contact with the gate trench portion 40.

Each mesa portion may have a contact region 15 exposed on the upper surface of the semiconductor substrate 10. The contact region 15 is a region of the P+ type having a higher concentration than the base region. The contact region 15 is provided between the base region and the upper surface of the semiconductor substrate 10. Providing the contact region 15 can reduce contact resistance between the semiconductor substrate 10 and the upper surface electrode 52. The emitter region 12 and the contact region 15 are connected to the upper surface electrode 52 through the first contact hole 54.

Each of the contact region 15 and the emitter region 12 in the mesa portion in the present example is provided from one trench portion to another trench portion of trench portions adjacent to each other in the X axis direction. The contact region 15 and the emitter region 12 are alternately arranged along the Y axis direction.

A contact region, which is provided at the very end, of a plurality of contact regions 15 discretely arranged in the Y axis direction, is referred to as a contact region 15-e. The contact region 15-e may be connected to the well region 11. In stead of the contact region 15-e, the base region may be exposed on the upper surface of the semiconductor substrate 10.

In another example, the contact region 15 and the emitter region 12 in the mesa portion may be provided in stripes along the Y axis direction. For example, the emitter region 12 may be provided in a region in contact with each trench portion, and the contact region 15 may be provided in a region sandwiched between emitter regions 12.

FIG. 2 shows a structure of a vicinity of one end portion of the trench portion in the Y axis direction. A similar structure may be provided in a vicinity of another end portion of the trench portion. For example, another end portion of the gate trench portion 40 in the Y axis direction may also extend into the well region 11 and be connected to the gate runner.

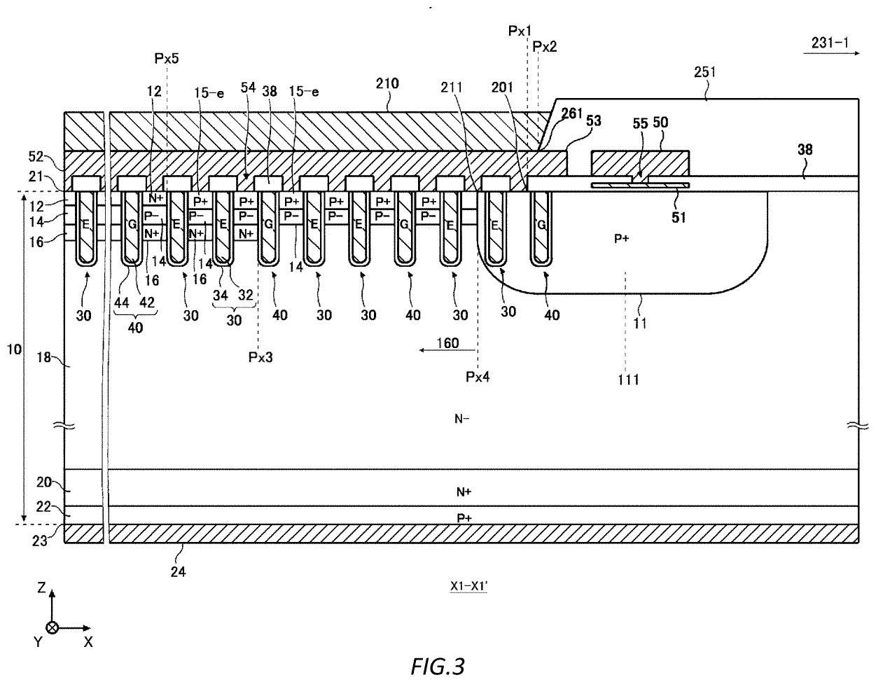

FIG. 3 shows one example of a cross section X1-X1′ in FIG. 2. The cross section X1-X1′ is the XZ plane passing through the emitter region 12 and the well region 11 in the vicinity of the end side 231-1. In the present example, the end side 231-1 may be the first end side. In another example, the end side 231-1 may be an end side 231 other than the first end side. The well region 11 in FIG. 3 is arranged facing the end side 231-1, and extends in the Y axis direction. The cross section X1-X1′ in FIG. 3 also includes an outside of the well region 11. An edge termination structure portion such as a guard ring of the P type may be provided outside the well region 11, but is omitted in FIG. 3.

Each cross sectional view in the present specification may indicate, by an arrow, a direction in which any end side 231 of the semiconductor substrate 10 is arranged. FIG. 3 indicates a direction of the end side 231-1 by an arrow. The semiconductor device 100 in the present example has, in the cross section, the semiconductor substrate 10, an interlayer dielectric film 38, a first gate runner 50, a second gate runner 51, the upper surface electrode 52, a plating layer 210, the protection film 251, and a collector electrode 24.

The semiconductor substrate 10 has the upper surface 21 and a lower surface 23. The interlayer dielectric film 38 is provided between the upper surface of the semiconductor substrate 10 and the upper surface electrode 52. The interlayer dielectric film 38 is a film including at least one of a dielectric film such as silicate glass to which an impurity such as boron or phosphorus is added, a thermal oxide film, or another dielectric film. The first contact hole 54 and a second contact hole 55 are provided in the interlayer dielectric film 38 in the cross section.

The upper surface electrode 52 is provided above the interlayer dielectric film 38. The upper surface electrode 52 is connected to the upper surface 21 of the semiconductor substrate 10 through the first contact hole 54 in the interlayer dielectric film 38.

The first gate runner 50 is provided above the interlayer dielectric film 38, and the second gate runner 51 is provided between the first gate runner 50 and the semiconductor substrate 10. The interlayer dielectric film 38 or another dielectric film is provided between the second gate runner 51 and the semiconductor substrate 10. The interlayer dielectric film 38 is provided between the first gate runner 50 and the second gate runner 51. The first gate runner 50 is electrically connected to the second gate runner 51 through the second contact hole 55. The first gate runner 50 is a metal wiring formed of aluminum or the like, for example. The second gate runner 51 is a wiring formed of polysilicon or the like, for example. The first gate runner 50, the second gate runner 51, and the second contact hole 55 may be provided enclosing the active portion 160 in a top view. The second gate runner 51 is connected to a gate conductive portion 42, which will be described later, in a vicinity of an edge of the gate trench portion 40.

The collector electrode 24 is provided on the lower surface 23 of the semiconductor substrate 10. The upper surface electrode 52 and the collector electrode 24 are formed of a metal material such as aluminum. In the present specification, a direction connecting the upper surface electrode 52 and the collector electrode 24 (the Z axis direction) is referred to as a depth direction.

The semiconductor substrate 10 has the drift region 18 of the N-type. The drift region 18 may be provided over an entirety of the semiconductor substrate 10 in a top view. The well region 11 encloses the upper surface electrode 52 in a top view. The well region 11 is a region of the P+ type exposed on the upper surface 21 of the semiconductor substrate 10. The well region 11 may be formed to a greater depth than the gate trench portion 40 and the dummy trench portion 30.

An end portion of the upper surface electrode 52 may overlap with the well region 11 in a top view. The first gate runner 50 and the second gate runner 51 overlap with the well region 11 in a top view. In a top view, an entirety of the first gate runner 50 and an entirety of the second gate runner 51 may overlap with the well region 11.

The protection film 251 is provided on the interlayer dielectric film 38. At least part of the protection film 251 is provided so as to cover the upper surface 53 of the upper surface electrode 52. The protection film 251 in the present example also covers the entirety of the first gate runner 50. The protection film 251 may be continuously provided from the upper surface electrode 52 to an end side of the semiconductor substrate 10 (the end side 231-1 in the present example). Part of the protection film 251 may be in contact with the interlayer dielectric film 38.

The plating layer 210 is provided on the upper surface 53 of the upper surface electrode 52. The plating layer 210 is provided on a region, which is not covered with the protection film 251, of the upper surface 53 of the upper surface electrode 52. The plating layer 210 may contain at least one of nickel or copper. The plating layer 210 may be a nickel plate, or may be a copper plate. The plating layer 210 may be in contact with the protection film 251, or may be away from it.

A wiring such as a linear wire or a plate-like lead frame connecting an external circuit and the semiconductor device 100 may be connected to the plating layer 210. The wiring may be soldered or crimped to the plating layer 210.

The upper surface 21 of the semiconductor substrate 10 is provided with a plurality of trench portions. Each trench portion will be described later in detail. Each trench portion is formed from the upper surface 21 of the semiconductor substrate 10 to a predetermined depth. In the cross section shown in FIG. 3, the plurality of trench portions are lined up at a predetermined interval in the X axis direction. At least some trench portions are provided below the upper surface electrode 52. Some trench portions may be arranged farther outward than the upper surface electrode 52. Some trench portions may be arranged inside the well region 11.

Each mesa portion sandwiched between two trench portions in the X axis direction is provided with the base region 14 of a P-type. The base region 14 may be in contact with trench portions on both sides of the mesa portion. In the present specification, a region sandwiched between two trench portions which are not arranged in the well region 11 is referred to as the mesa portion. The drift region 18 is provided below the base region 14.

At least part of the mesa portion is provided with the emitter region 12 of an N+ type. In addition, part of the mesa portion may be provided with the contact region 15 of the P+ type in stead of the emitter region 12. In the examples shown in FIG. 2 and FIG. 3, one or more mesa portions closest to the well region 11 are not provided with the emitter regions 12, but are provided with contact regions 15-e. Arranging the contact regions 15-e in the mesa portions makes it easier to extract holes to the upper surface electrode 52 via the mesa portions.

The emitter region 12 and the contact region 15 are exposed on the upper surface 21 of the semiconductor substrate 10. The emitter region 12 has a higher doping concentration than the drift region 18. The contact region 15 has a higher doping concentration than the base region 14.

The emitter region 12 and the contact region 15 are arranged between the base region 14 and the upper surface 21 of the semiconductor substrate 10. At least part of the emitter region 12 is provided in contact with the gate trench portion 40.

When a predetermined on-voltage is applied to the gate conductive portion 42 of the gate trench portion 40, a surface layer, which is in contact with the gate trench portion 40, of the base region 14 is inverted to an N type, to form a channel layer. This provides electrical continuity between the emitter region 12 and the drift region 18, to turn on a transistor.

At least part of the mesa portion may be provided with the accumulation region 16 of the N type. The accumulation region 16 is arranged between the base region 14 and the drift region 18. The accumulation region 16 is a region of the N type having a higher doping concentration than the drift region 18. Providing the accumulation region 16 having a high concentration between the drift region 18 and the base region 14 can increase a carrier injection enhancement effect (IE effect) and reduce an on-voltage. The accumulation region 16 may be provided so as to cover an entirety of a lower surface of the base region 14 in each mesa portion.

A buffer region 20 of the N+ type may be provided below the drift region 18. A doping concentration in the buffer region 20 is higher than a doping concentration in the drift region 18. The buffer region 20 may have two or more concentration peaks in a depth direction of the semiconductor substrate 10 (the Z axis direction). The buffer region 20 may serve as a field stopper layer which prevents a depletion layer expanding from a lower end of the base region 14 from reaching a collector region 22 of the P+ type. If the semiconductor substrate 10 is provided with a MOSFET, the buffer region 20 may not be provided.

In the semiconductor substrate 10, the collector region 22 of the P+ type is provided below the buffer region 20. An acceptor concentration in the collector region 22 is higher than an acceptor concentration in the base region 14. The collector region 22 is connected to the collector electrode 24. The collector electrode 24 is formed of a metal material such as aluminum. If the semiconductor substrate 10 is provided with a MOSFET, a drain region of the N+ type is provided in stead of the collector region 22. If the semiconductor substrate 10 is provided with a diode, an anode region of the P type is provided in stead of the emitter region 12, and a cathode region of the N+ type is provided in stead of the collector region 22.

One or more gate trench portions 40 and one or more dummy trench portions 30 are provided on a side of the upper surface 21 of the semiconductor substrate 10. In each figure, the gate trench portion 40 may be denoted by a symbol G, and the dummy trench portion 30 may be denoted by a symbol E. Each trench portion is provided from the upper surface 21 of the semiconductor substrate 10 through the base region 14 to a position below the base region 14. In a region provided with at least any one of the emitter region 12, the contact region 15, or the accumulation region 16, each trench portion also passes through these doping regions. A configuration in which a trench portion passes through a doping region is not limited to a configuration which is manufactured by forming a doping region and then forming a trench portion. The configuration in which a trench portion passes through a doping region also includes a configuration which is manufactured by forming trench portions and then forming a doping region between the trench portions.

The gate trench portion 40 has a gate dielectric film 44 and the gate conductive portion 42. The gate dielectric film 44 is provided covering an inner wall of a trench provided from the upper surface 21 of the semiconductor substrate 10 into the semiconductor substrate 10. The gate dielectric film 44 may be formed by oxidizing or nitriding the semiconductor substrate 10 exposed on the inner wall of the trench. The gate conductive portion 42 is provided farther inward than the gate dielectric film 44 inside the trench. In other words, the gate dielectric film 44 insulates the gate conductive portion 42 from the semiconductor substrate 10. The gate conductive portion 42 is formed of a conductive material such as polysilicon.

The gate conductive portion 42 may be provided longer than the base region 14 in the depth direction. The gate trench portion 40 in the cross section is covered with the interlayer dielectric film 38 on the upper surface 21 of the semiconductor substrate 10. The gate conductive portion 42 is electrically connected to the second gate runner 51. When a predetermined gate voltage is applied to the gate conductive portion 42, a channel due to an electron inversion layer is formed in a surface layer at a boundary, which is in contact with the gate trench portion 40, of the base region 14.

The dummy trench portions 30 may have the same structure as that of the gate trench portions 40 in the cross section. The dummy trench portion 30 has a dummy dielectric film 34 and a dummy conductive portion 32. The dummy conductive portion 32 is electrically connected to the upper surface electrode 52. The dummy dielectric film 34 is provided covering an inner wall of a trench. The dummy conductive portion 32 is provided inside the trench and is provided farther inward than the dummy dielectric film 34. The dummy dielectric film 34 insulates the dummy conductive portion 32 from the semiconductor substrate 10. The dummy conductive portion 32 may be formed of the same material as that of the gate conductive portion 42. For example, the dummy conductive portion 32 is formed of a conductive material such as polysilicon. The dummy conductive portion 32 may have the same length as that of the gate conductive portion 42 in the depth direction.

In the present example, the first contact hole 54 refers to a contact hole, which connects the upper surface electrode 52 to the well region 11 or the active portion 160, of contact holes provided in the interlayer dielectric film 38. As shown in FIG. 3 or the like, a plurality of first contact holes 54 may be provided in the interlayer dielectric film 38. The first contact hole 54 may refer to a contact hole connecting the upper surface electrode 52 to the upper surface 21 of the semiconductor substrate 10 in a region farther inward than the first gate runner 50 or the second gate runner 51. The first contact hole 54 may refer to a contact hole connecting the upper surface electrode 52 to the upper surface 21 of the semiconductor substrate 10 in a region farther inward than a center 111 of the well region 11 in a direction from an end portion of the active portion 160 toward the closest end side 231 (in FIG. 3, the X axis direction). A contact hole, which is in contact with the upper surface 21 of the semiconductor substrate 10 in a region farther outward than the well region 11, of the contact holes provided in the interlayer dielectric film 38, may be excluded from the first contact holes 54.

The first contact hole 54 in the example shown in FIG. 3 has at least one of a well hole end portion 201 or an active hole end portion 211. The well hole end portion 201 electrically connects the upper surface electrode 52 to the well region 11. The well hole end portion 201 is a portion, which is closest to the end side 231-1 in the X axis direction, of the first contact hole 54 arranged overlapping with the well region 11.

The active hole end portion 211 electrically connects the upper surface electrode 52 to the active portion 160. The active hole end portion 211 is a portion, which is closest to the end side 231-1 in the X axis direction, of the first contact hole 54 arranged overlapping with the active portion 160.

The well hole end portion 201 and the active hole end portion 211 may each be a portion, which is in contact with the upper surface 21 of the semiconductor substrate 10, of the first contact hole 54. In the example shown in FIG. 3, the well hole end portion 201 is a portion where a side surface of the interlayer dielectric film 38 is in contact with the well region 11, and in the example shown in FIG. 3, the active hole end portion 211 is a boundary portion, exposed by the first contact hole 54, between the well region 11 and the active portion 160.

The first contact hole 54 has a first outer hole end portion closest to the first end side of the semiconductor substrate 10. If the end side 231-1 is the first end side, a portion, which is closest to the end side 231-1 in the X axis direction, of the first contact hole 54 is referred to as the first outer hole end portion. If the end side 231-1 is the first end side, the well hole end portion 201 shown in FIG. 3 is one example of the first outer hole end portion. If the well hole end portion 201 is not provided, the active hole end portion 211 serves as the first outer hole end portion. The first outer hole end portion is provided for each of the two end sides 231-1 and 231-3 of the semiconductor substrate 10. In addition, if the end side 231-1 is the second end side, a portion, which is closest to the end side 231-1 in the X axis direction, of the first contact hole 54 is referred to as a second outer hole end portion. Similarly, if the end side 231-1 is the third end side, a portion, which is closest to the end side 231-1 in the X axis direction, of the first contact hole 54 is referred to as a third outer hole end portion.

The plating layer 210 is formed on the upper surface 53, which overlaps with the first outer hole end portion in a top view, of the upper surface electrode 52. The plating layer 210 may also be formed on the upper surface 53, which overlaps with the second outer hole end portion, of the upper surface electrode 52 and on the upper surface 53, which overlaps with the third outer hole end portion, of the upper surface electrode 52. In addition, in each end side 231 of the semiconductor substrate 10, a portion, which is closest to the end side 231, of the first contact hole 54 is referred to as an outer hole end portion. In every outer hole end portion, the plating layer 210 may be formed on the upper surface 53, which overlaps with the outer hole end portion, of the upper surface electrode 52. In the present example, the plating layer 210 is formed on the upper surface 53, which overlaps with the outer hole end portion, of the upper surface electrode 52, for each of the end sides 231-1, 231-2, 231-3, and 231-4.

In the present example, the plating layer 210 is formed on the upper surface 53 of the upper surface electrode 52 overlapping with the well hole end portion 201. The plating layer 210 may also be formed on the upper surface 53 of the upper surface electrode 52 overlapping with the active hole end portion 211. The plating layer 210 may be continuously formed from a position above the well hole end portion 201 to a position above the active hole end portion 211.

Forming the plating layer 210 on the upper surface electrode 52 overlapping with the first outer hole end portion can suppress generation of stress in the upper surface electrode 52. During actual use or the like, temperature in the upper surface electrode 52 may be repeatedly changed, to generate the stress. In this case, stress migration may be caused in the upper surface electrode 52. Particularly, if the upper surface electrode 52 contains aluminum, the stress migration is easily caused. When the stress migration is caused, movement of electron holes in the upper surface electrode 52 in the XY plane is suppressed. It is to be noted that, if the semiconductor substrate 10 is a silicon carbide substrate, it is often used in an environment with a substantial temperature fluctuation, and the stress generated in the upper surface electrode 52 becomes large. In addition, similarly, when the semiconductor device 100 is mounted on a semiconductor module including a water cooling apparatus, it is often used in an environment with a substantial temperature fluctuation.

In contrast, providing the plating layer 210 above the first outer hole end portion can suppress deformation of the upper surface electrode 52 in a vicinity of the first outer hole end portion and suppress the generation of the stress, compared to when providing the protection film 251 so as to overlap with the first outer hole end portion. The plating layer 210 may be continuously provided from the first outer hole end portion to a center of the semiconductor substrate 10 in a top view. The upper surface 53 of the upper surface electrode 52 may not be provided with a protection film in a region farther inward than the first outer hole end portion. In another example, the upper surface 53 of the upper surface electrode 52 may be provided with a protection film in the region farther inward than the first outer hole end portion.

In the present example, electron holes (holes) which have reached the first outer hole end portion from the semiconductor substrate 10 can move in the Z axis direction from the upper surface electrode 52 to the plating layer 210. The electron holes which have reached the upper surface electrode 52 from the first outer hole end portion hardly move in the X axis direction in the upper surface electrode 52. Therefore, even if the stress migration or the like is caused in the upper surface electrode 52, movement of the electron holes from the upper surface electrode 52 to the plating layer 210 is hardly suppressed.

The protection film 251 in the present example is entirely provided between the first outer hole end portion and the first end side (the end side 231-1 in the example shown in FIG. 3) in a top view. The protection film 251 is one example of an outer protection portion. The protection film 251 has an inner protection end portion 261. The inner protection end portion 261 is a portion, which is closest to the first contact hole 54, of the protection film 251. The inner protection end portion 261 may be a portion, which is in contact with the upper surface 53 of the upper surface electrode 52, of a side surface of the protection film 251. The inner protection end portion 261 is provided between the well hole end portion 201 and the end side 231-1 in a top view.

A position of the well hole end portion 201 in the X axis direction is referred to as Px1, and a position of the inner protection end portion 261 in the X axis direction is referred to as Px2. If the well hole end portion 201 is not provided, a position of the active hole end portion 211 in the X axis direction is referred to as Px1. A position in the X axis direction of a portion, which is closest to the end side 231-1, of the accumulation region 16 is referred to as Px3. A position in the X axis direction of a portion, which is farthest inward in the X axis direction, of the well region 11 is referred to as Px4. A position in the X axis direction of a portion, which is closest to the end side 231-1, of the emitter region 12 is referred to as Px5.

The position Px1 is arranged farther inward than the position Px2 (in other words, on a side closer to the center of the active portion 160). The position Px1 and the position Px2 may both be arranged farther inward than the center 111 of the well region 11. The position Px1 and the position Px2 may both be arranged overlapping with the well region 11. In other words, the position Px1 and the position Px2 may be arranged between the center 111 and the position Px4. In another example, the position Px2 may overlap with the well region 11, and the position Px1 may be arranged farther inward than the position Px4. In addition, the position Px1 and the position Px2 may both be arranged farther inward than the position Px4.

In another example, the position Px2 may be arranged farther outward than the center 111 of the well region 11, and the position Px1 may be arranged farther inward than the center 111. In this case as well, the position Px2 may overlap with the well region 11. The position Px1 may be farther outward or inward than the position Px4.

The position Px1 and the position Px2 may both be arranged farther outward than the position Px3. In other words, in the X axis direction, the outer hole end portion and the inner protection end portion 261 may be provided between the accumulation region 16 and the end side 231-1. In addition, the position Px1 and the position Px2 may both be arranged farther outward than the position Px5.

A distance between the position Px1 and the position Px2 in the X axis direction may be smaller than a width of the well region 11 in the X axis direction. Decreasing the distance between the position Px1 and the position Px2 allows the protection film 251 to protect a wider range. The distance between the position Px1 and the position Px2 may be equal to or smaller than half the width of the well region 11, may be 10 μm or smaller, or may be 5 μm or smaller. The distance may be 0 μm, or may be larger than 0 μm.

The position Px2 may be arranged farther outward than a trench portion, which is closest to the end side 231-1, of the plurality of trench portions. As shown in FIG. 3, the position Px2 may overlap with the trench portion closest to the end side 231-1. The position Px2 may be arranged farther inward than the trench portion closest to the end side 231-1.

The first contact hole 54 has the active hole end portion 211, which is closest to the first end side (the end side 231-1 in the present example), of a portion connecting the active portion 160 and the upper surface electrode 52. The position of the active hole end portion 211 in the present example in the X axis direction matches the position Px4 which is a position of an end portion of the well region 11. In another example, the active hole end portion 211 may be arranged farther inward than the position Px4.

In the X axis direction, the inner protection end portion 261 may be provided between the contact region 15 and the end side 231-1. In the example shown in FIG. 3, the position Px4 matches a position of an outer end portion of the contact region 15. The inner protection end portion 261 may be arranged between the position Px4 and the end side 231-1.

In a top view, the plating layer 210 is provided on the upper surface 53 of the upper surface electrode 52 overlapping with the active hole end portion 211. Since there are a relatively large number of electron holes in the active portion 160, a relatively large number of electron holes reach the active hole end portion 211. Providing the plating layer 210 above the active hole end portion 211 can suppress stress in a portion, through which a relatively large number of electron holes flow, in the upper surface electrode 52.

As shown in FIG. 3, the active hole end portion 211 may be arranged farther inward than the well hole end portion 201. In another example, at a position overlapping with the well region 11, the first contact hole 54 may not be provided, and the well hole end portion 201 may not be provided.

The plating layer 210 may be continuously provided in the X axis direction from the active hole end portion 211 to a position farther inward than the position Px3. The plating layer 210 may be continuously provided in the X axis direction from the active hole end portion 211 to a position farther inward than the position Px5. The plating layer 210 may be continuously provided in the X axis direction from the active hole end portion 211 to the center of the active portion 160.

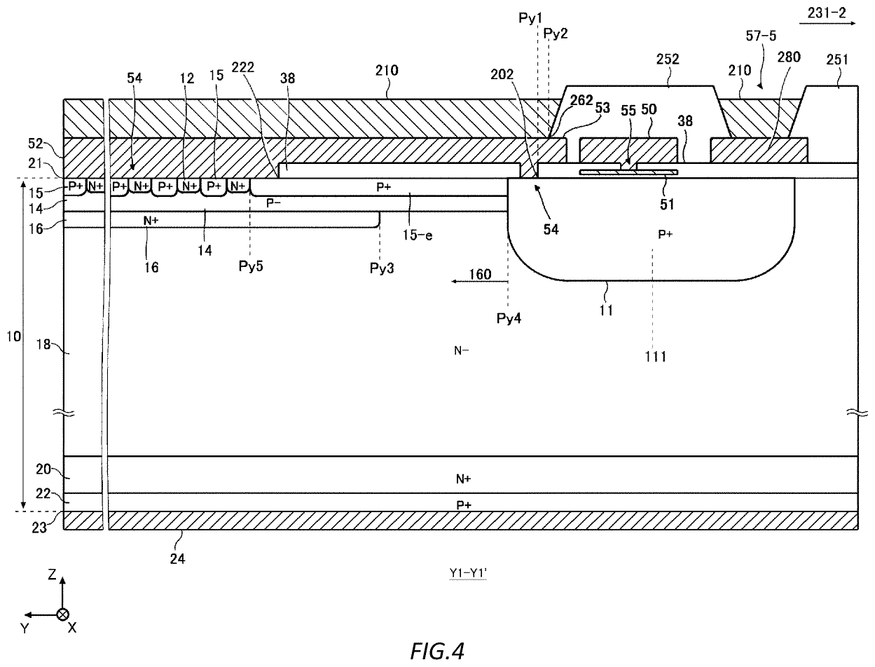

FIG. 4 shows one example of a cross section Y1-Y1′ in FIG. 2. The cross section Y1-Y1′ is the YZ plane passing through the first contact hole 54 and the well region 11 in the vicinity of the end side 231-2. In the present example, the end side 231-2 may be the first end side. In this case, the end side 231-1 is the second end side or the third end side. If the end side 231-1 is the second end side or the third end side, the protection film 251 may be provided or the plating layer 210 may be provided above the well hole end portion 201 shown in FIG. 3. In addition, the protection film 251 may be provided or the plating layer 210 may be provided above the active hole end portion 211.

The well region 11 in FIG. 4 is arranged facing the end side 231-2 and extends in the X axis direction. The cross section Y1-Y1′ in FIG. 4 also includes an outside of the well region 11. An edge termination structure portion such as a guard ring may be provided outside the well region 11, but is omitted in FIG. 4.

FIG. 4 indicates a direction of the end side 231-2 by an arrow. The semiconductor device 100 in the present example has, in the cross section, the semiconductor substrate 10, the interlayer dielectric film 38, the first gate runner 50, the second gate runner 51, the upper surface electrode 52, a pad electrode 280, a pad 57-5, the plating layer 210, the protection film 251, the protection film 252, and the collector electrode 24. Components, which are denoted by the same reference numerals as in FIG. 3, of the components shown in FIG. 4 have the same structures and functions as those described in FIG. 3.

An end portion of the upper surface electrode 52 in the present example in the Y axis direction may overlap with the well region 11 in a top view. In the present example, the pad 57-5 is provided farther outward than the first gate runner 50 and the second gate runner 51. The pad 57-5 may be connected to a diode for detecting temperature, or the like. The pad 57-5 is provided above the interlayer dielectric film 38. The pad 57-5 in the present example has the pad electrode 280 and the plating layer 210. The pad electrode 280 may be formed of the same material as that of the upper surface electrode 52. The pad electrode 280 is provided separately from the upper surface electrode 52. The plating layer 210 is formed on an upper surface of the pad electrode 280. A wiring such as a wire may be connected to an upper surface of the plating layer 210.

The protection film 251 and the protection film 252 are provided on the interlayer dielectric film 38. The protection film 251 is provided so as to cover part of the upper surface of the pad electrode 280. The protection film 251 may be continuously provided from the pad electrode 280 to an end side of the semiconductor substrate 10 (the end side 231-2 in the present example). Part of the protection film 251 may be in contact with the interlayer dielectric film 38.

The protection film 252 is provided so as to cover part of the upper surface of the pad electrode 280. The plating layer 210 is provided on a region, which is not covered with the protection film 251 and the protection film 252, of the upper surface of the pad electrode 280. In another example, the pad 57-5 may not be provided with the plating layer 210. The protection film 252 is provided so as to cover part of an upper surface of the upper surface electrode 52. In addition, the protection film 252 also covers the entirety of the first gate runner 50. The protection film 252 may be in contact with the interlayer dielectric film 38 between the pad electrode 280 and the first gate runner 50 and between the first gate runner 50 and the upper surface electrode 52.

The first contact hole 54 provided in the active portion 160 is provided extending in the Y axis direction. The emitter region 12 and the contact region 15 are alternately arranged along the Y axis direction. The first contact hole 54 in the present example exposes the emitter region 12 and the contact region 15.

The first contact hole 54 may also be provided at a position overlapping with the well region 11. The interlayer dielectric film 38 may be provided between the first contact hole 54 of the active portion 160 and the first contact hole 54 of the well region 11.

The first contact hole 54 in the example shown in FIG. 4 has at least one of a well hole end portion 202 or an active hole end portion 222. The well hole end portion 202 electrically connects the upper surface electrode 52 and the well region 11. The well hole end portion 202 is a portion, which is closest to the end side 231-2 in the Y axis direction, of the first contact hole 54 arranged overlapping with the well region 11.

The active hole end portion 222 electrically connects the upper surface electrode 52 and the active portion 160. The active hole end portion 222 is a portion, which is closest to the end side 231-2 in the Y axis direction, of the first contact hole 54 arranged overlapping with the active portion 160.

The well hole end portion 202 and the active hole end portion 222 may each be a portion, which is in contact with the upper surface 21 of the semiconductor substrate 10, of the first contact hole 54. In the example shown in FIG. 4, the well hole end portion 202 is a portion where a side surface of the interlayer dielectric film 38 is in contact with the well region 11, and in the example shown in FIG. 4, the active hole end portion 222 is a portion where a side surface of the interlayer dielectric film 38 is in contact with the contact region 15 or the emitter region 12.

The first contact hole 54 has a first outer hole end portion closest to the first end side of the semiconductor substrate 10. If the end side 231-2 is the first end side, a portion, which is closest to the end side 231-2 in the Y axis direction, of the first contact hole 54 is referred to as the first outer hole end portion. If the end side 231-2 is the first end side, the well hole end portion 202 shown in FIG. 4 is one example of the first outer hole end portion. If the well hole end portion 202 is not provided, the active hole end portion 222 serves as the first outer hole end portion. If the end side 231-2 is the second end side, a portion, which is closest to the end side 231-2 in the Y axis direction, of the first contact hole 54 is referred to as the second outer hole end portion. Similarly, if the end side 231-2 is the third end side, a portion, which is closest to the end side 231-2 in the Y axis direction, of the first contact hole 54 is referred to as the third outer hole end portion.

In the present example, the plating layer 210 is formed on the upper surface 53 of the upper surface electrode 52 overlapping with the well hole end portion 202. The plating layer 210 may also be formed on the upper surface 53 of the upper surface electrode 52 overlapping with the active hole end portion 222. The plating layer 210 may be continuously formed from a position above the well hole end portion 202 to a position above the active hole end portion 222.

In the present example as well, it is possible to suppress deformation of the upper surface electrode 52 in a vicinity of the first outer hole end portion and suppress generation of stress. In addition, even if the stress migration or the like is caused in the upper surface electrode 52, movement of electron holes in the upper surface electrode 52 is hardly suppressed.

The protection film 251 and the protection film 252 in the present example are entirely provided between the first outer hole end portion and the first end side (the end side 231-2 in the example shown in FIG. 4) in a top view. The protection film 251 and the protection film 252 are examples of outer protection portions. The protection film 252 has an inner protection end portion 262. The inner protection end portion 262 is a portion, which is closest to the first contact hole 54, of the protection film 252. The inner protection end portion 262 may be a portion where a side surface of the protection film 252 is in contact with the upper surface 53 of the upper surface electrode 52. The inner protection end portion 262 is provided between the well hole end portion 202 and the end side 231-2 in a top view.

A position of the well hole end portion 202 in the Y axis direction is referred to as Py1, and a position of the inner protection end portion 262 in the Y axis direction is referred to as Py2. If the well hole end portion 202 is not provided, a position of the active hole end portion 222 in the Y axis direction is referred to as Py1. A position in the Y axis direction of a portion, which is closest to the end side 231-2, of the accumulation region 16 is referred to as Py3. A position in the Y axis direction of a portion, which is farthest inward in the Y axis direction, of the well region 11 is referred to as Py4. A position in the Y axis direction of a portion, which is closest to the end side 231-2, of the emitter region 12 is referred to as Py5.

The position Py1 is arranged farther inward than the position Py2 (in other words, on a side closer to the center of the active portion 160). The position Py1 and the position Py2 may both be arranged farther inward than the center 111 of the well region 11. The position Py1 and the position Py2 may both be arranged overlapping with the well region 11. In other words, the position Py1 and the position Py2 may be arranged between the center 111 and the position Py4. In another example, the position Py2 may overlap with the well region 11, and the position Py1 may be arranged farther inward than the position Py4. In addition, the position Py1 and the position Py2 may both be arranged farther inward than the position Py4.

In another example, the position Py2 may be arranged farther outward than the center 111 of the well region 11, and the position Py1 may be arranged farther inward than the center 111. In this case as well, the position Py2 may overlap with the well region 11. The position Py1 may be farther outward or inward than the position Py4.

The position Py1 and the position Py2 may both be arranged farther outward than the position Py3. In other words, in the Y axis direction, the inner protection end portion 262 may be provided between the accumulation region 16 and the end side 231-2. In addition, the position Py1 and the position Py2 may both be arranged farther outward than the position Py5.

A distance between the position Py1 and the position Py2 in the X axis direction may be smaller than a width of the well region 11 in the X axis direction. Decreasing the distance between the position Py1 and the position Py2 allows the protection film 252 to protect a wider range. The distance between the position Py1 and the position Py2 may be equal to or smaller than half the width of the well region 11, may be 10 μm or smaller, or may be 5 μm or smaller. The distance may be 0 μm, or may be larger than 0 μm.

The position of the active hole end portion 222 in the present example in the Y axis direction is arranged farther inward than the position Py4 which is a position of an end portion of the well region 11. In another example, the active hole end portion 222 may match the position Py4.

In a top view, the plating layer 210 is provided on the upper surface 53 of the upper surface electrode 52 overlapping with the active hole end portion 222. Since there are a relatively large number of electron holes in the active portion 160, a relatively large number of electron holes reach the active hole end portion 222. Providing the plating layer 210 above the active hole end portion 222 can suppress stress in a portion, through which a relatively large number of electron holes flow, in the upper surface electrode 52.

The plating layer 210 may be continuously provided in the Y axis direction from the active hole end portion 222 to a position farther inward than the position Py3. The plating layer 210 may be continuously provided in the Y axis direction from the active hole end portion 222 to a position farther inward than the position Py5. The plating layer 210 may be continuously provided in the Y axis direction from the active hole end portion 222 to the center of the active portion 160.

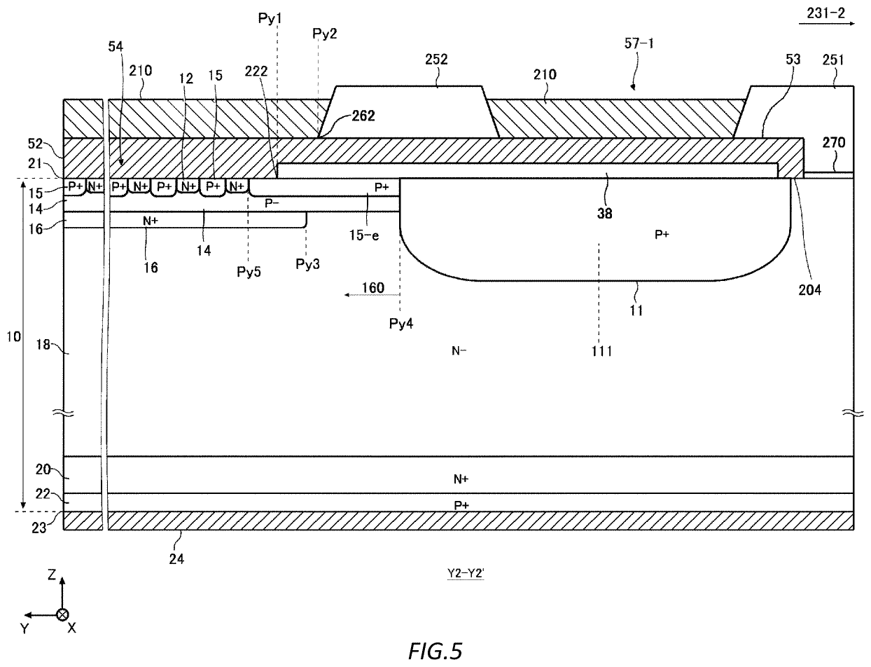

FIG. 5 shows one example of a cross section Y2-Y2′. As shown in FIG. 1, the cross section Y2-Y2′ is the YZ plane passing through a pad 57-1 in the vicinity of the end side 231-2. Except for a structure particularly described, a structure in the cross section Y2-Y2′ may be similar to a structure in the cross section Y1-Y1′. In the cross section Y2-Y2′ in the present example, the first gate runner 50 and the second gate runner 51 are not provided. The first gate runner 50 and the second gate runner 51 may be provided closer to the end side 231-2 than the pad 57-1.

The pad 57-1 is a pad at the same potential as the upper surface electrode 52. The pad 57-1 is also referred to as a Kelvin emitter pad. Detecting potential in the pad 57-1 can detect potential in the upper surface electrode 52. A wiring such as a wire may be connected to the pad 57-1.

The well region 11 is provided below the pad 57-1. A width of the well region 11 in the Y axis direction may be larger than or the same as that of the well region 11 shown in the cross section Y1-Y1′.

In the present example, the upper surface electrode 52 is provided extending to a region of the pad 57-1. The pad 57-1 in the present example has the upper surface electrode 52 and the plating layer 210. The plating layer 210 in the active portion 160 may be separated from the plating layer 210 in the pad 57-1 by the protection film 252. In another example, the protection film 252 may not be provided, and the plating layer 210 in the active portion 160 and the plating layer 210 in the pad 57-1 may be continuously provided.

The upper surface electrode 52 in the present example extends in the Y axis direction to a position farther outward than the well region 11 in a top view. In another example, the upper surface electrode 52 may terminate above the well region 11 in the Y axis direction. As shown in FIG. 3, the upper surface electrode 52 may have an outer connection portion 204 which is in contact with the semiconductor substrate 10 outside the well region 11. As described above, a portion which is in contact with the semiconductor substrate 10 in a region farther outward than the well region 11 is excluded from the first contact holes 54.

The protection film 251 is provided so as to cover part of the upper surface 53 of the upper surface electrode 52. The protection film 251 may be continuously provided from the upper surface electrode 52 to an end side of the semiconductor substrate 10 (the end side 231-2 in the present example). In a region farther outward than the upper surface electrode 52, the interlayer dielectric film 38 may be provided or a dielectric film 270 such as an oxide film may be provided between the protection film 251 and the semiconductor substrate 10.

The protection film 252 is provided on the upper surface 53 of the upper surface electrode 52. The protection film 252 may be in contact with the upper surface 53 of the upper surface electrode 52 over an entire length in the Y axis direction. Providing the protection film 252 can separate the plating layer 210 in the active portion 160 from the plating layer 210 in the pad 57-1. Using the protection film 252 as a reference position makes it easier to control a position at which a wiring such as a wire is connected to the pad 57-1. At least part of the protection film 252 may be arranged above the well region 11. At least part of the protection film 252 may be provided in the active portion 160.

The first contact hole 54 in the present example is not provided at a position overlapping with the well region 11. The first contact hole 54 in the present example has the active hole end portion 222, and does not have the well hole end portion 202. It should be noted that, in the present example as well, the first contact hole 54 may have the well hole end portion 202.

In the present example, the active hole end portion 222 serves as a first outer hole end portion. In the present example as well, the plating layer 210 is formed on the upper surface 53 of the upper surface electrode 52 overlapping with the active hole end portion 222. The plating layer 210 may be continuously provided in the Y axis direction from the active hole end portion 222 to a position farther inward than the position Py5. The plating layer 210 may be continuously provided in the Y axis direction from the active hole end portion 222 to the center of the active portion 160.

A position Py1 which is a position of the active hole end portion 222 is arranged farther inward than a position Py2 which is a position of the inner protection end portion 262. The position Py1 may be arranged farther outward or inward than the position Py3 which is a portion of an outer end portion of the accumulation region 16. In the example shown in FIG. 5, the position Py1 is arranged between the position Py3 and the position Py5. In another example, the position Py1 may be arranged farther inward than the position Py5.

The position Py2 is arranged farther outward than the position Py1. The position Py2 may be arranged farther inward than the position Py4. The position Py2 may be arranged between the position Py3 and the position Py4. In another example, the position Py2 may be arranged farther outward than the position Py4. The position Py2 may be arranged farther inward than the center 111 of the well region 11.

In the present example as well, it is possible to suppress deformation of the upper surface electrode 52 in a vicinity of the first outer hole end portion and suppress generation of stress. In addition, even if the stress migration or the like is caused in the upper surface electrode 52, movement of electron holes in the upper surface electrode 52 is hardly suppressed.

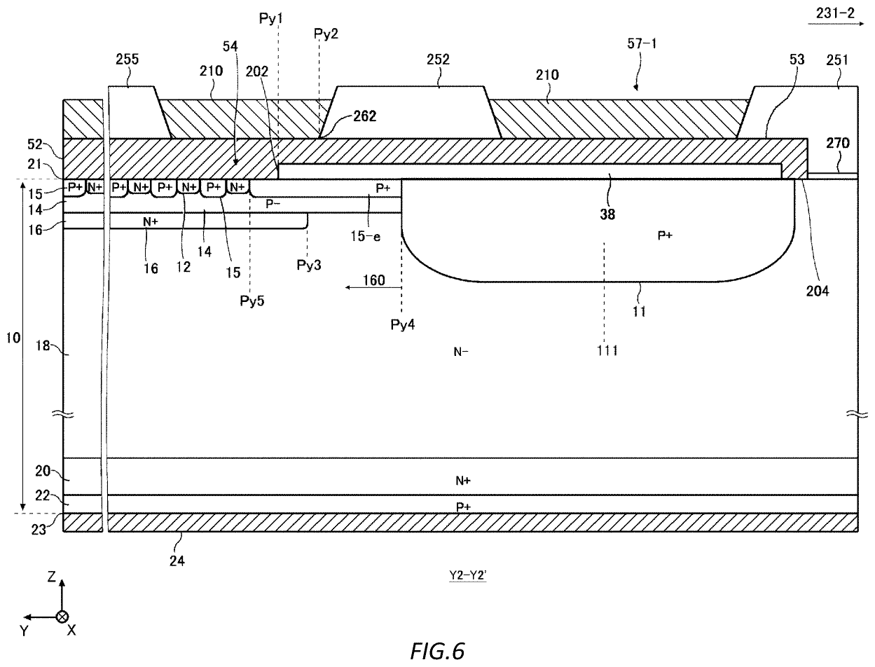

FIG. 6 shows another example of a cross section Y2-Y2′. The semiconductor device 100 in the present example further includes a protection film 255 in addition to each configuration described in the present specification. The protection film 255 is arranged farther away from the end side 231-2 than an outer protection portion (the protection film 251 and the protection film 252 in the present example) in a top view, and is arranged overlapping with the first contact hole 54. The protection film 255 is one example of an inner protection portion.

The plating layer 210 is provided between the protection film 255 and the protection film 252. The protection film 255 may be arranged between the protection film 253 shown in FIG. 1 and the protection film 255. The protection film 255 may extend in the X axis direction and be connected to the protection film 251, or may be separated from the protection film 251 in the X axis direction. A width of the protection film 255 in the Y axis direction may be smaller than a width of the protection film 252 in the Y axis direction, or may be smaller than a width of the protection film 251 in the Y axis direction.

A wiring such as a wire may be soldered to the plating layer 210 of the active portion 160 in a region farther inward than the protection film 255. Providing the protection film 255 can prevent solder from flowing to a region farther outward than the protection film 255. This can prevent the solder in the active portion 160 from scattering to another pad 57. The protection film 255 may also be provided in the cross section Y1-Y1′ shown in FIG. 4. The protection film 255 may be provided extending in the X axis direction so as to connect the protection film 251 and the protection film 254, between the protection film 252 and the protection film 253 shown in FIG. 1.

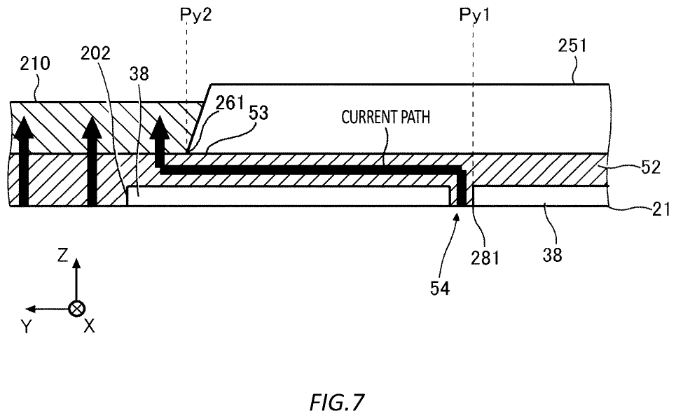

FIG. 7 illustrates a path of an electron hole current from an outer hole end portion 281 in a comparative example. As described above, the outer hole end portion 281 is either a well hole end portion 202 or an active hole end portion 222. In the comparative example, a protection film 251 is provided on an upper surface 53 of an upper surface electrode 52 at a position Py1 which is a position of the outer hole end portion 281. The protection film 251 extends in the Y axis direction to a position farther inward than the outer hole end portion 281.

In the present example, the electron hole current from the outer hole end portion 281 flows inside the upper surface electrode 52 along the Y axis direction, to reach a plating layer 210. When the upper surface electrode 52 has a crack or the like, a resistance value for the electron hole current flowing in the Y axis direction increases, making it difficult for the electron hole current from the outer hole end portion 281 to flow.

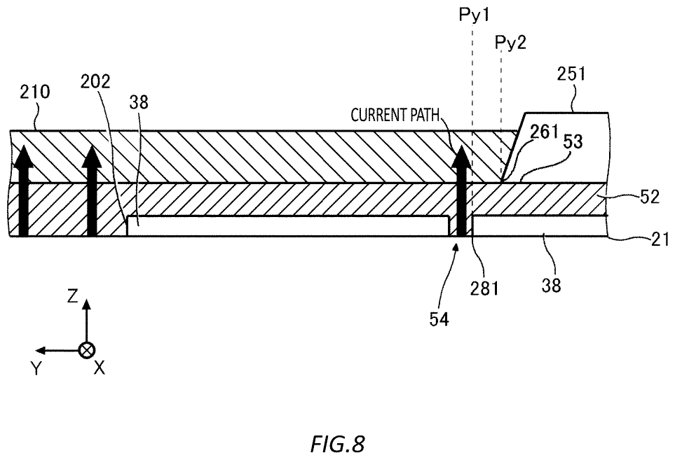

FIG. 8 illustrates a path of an electron hole current from an outer hole end portion 281 in an embodiment example. In the embodiment example, as described in FIG. 1 to FIG. 6, a plating layer 210 is provided on an upper surface 53 of an upper surface electrode 52 at a position Py1 which is a position of the outer hole end portion 281. A protection film 251 is provided farther outward than the outer hole end portion 281.

In the present example, the plating layer 210 is provided above the outer hole end portion 281, and a region covered with the plating layer 210 is larger than in the example shown in FIG. 7. Therefore, it is possible to suppress generation of stress in the upper surface electrode 52 and suppress generation of a crack or the like in the upper surface electrode 52. In addition, in the present example, the electron hole current from the outer hole end portion 281 flows to the plating layer 210 directly above. Therefore, even if the upper surface electrode 52 has a crack or the like, the electron hole current from the outer hole end portion 281 can flow to the plating layer 210 without being obstructed.

While the present invention has been described by way of the embodiments, the technical scope of the present invention is not limited to the above-described embodiments. It is apparent to persons skilled in the art that various alterations or improvements can be made to the above described embodiments. It is also apparent from the description of the claims that embodiments added with such alterations or improvements can be included in the technical scope of the present invention.

Note that the operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the operation flow is described by using phrases such as “first” or “next” in the scope of the claims, specification, or drawings, it does not necessarily mean that the process must be performed in this order.

What is claimed is:

1. A semiconductor device comprising:
a semiconductor substrate having an upper surface and a lower surface;
an upper surface electrode containing aluminum;
an interlayer dielectric film provided between the upper surface of the semiconductor substrate and the upper surface electrode and having a first contact hole connecting the semiconductor substrate and the upper surface electrode;
a protection film provided on an upper surface of the upper surface electrode; and
a plating layer provided on a region, which is not covered with the protection film, of the upper surface of the upper surface electrode, wherein
the semiconductor substrate has a first end side in a top view,
the first contact hole includes a first outer hole end portion closest to the first end side, and
the plating layer is formed on a portion, which overlaps with the first outer hole end portion, of the upper surface electrode.

2. The semiconductor device according to claim 1, wherein
the protection film has an outer protection portion provided between the first outer hole end portion and the first end side in a top view.

3. The semiconductor device according to claim 2, wherein
an inner protection end portion, which is closest to the first contact hole, of the outer protection portion is provided between the first outer hole end portion and the first end side.

4. The semiconductor device according to claim 3, wherein
the protection film further has an inner protection portion arranged farther away from the first end side than the outer protection portion in a top view and arranged overlapping with the first contact hole.

5. The semiconductor device according to claim 1, wherein
the semiconductor substrate has an active portion in which a semiconductor element is formed,
the first contact hole has an active hole end portion, which is closest to the first end side, of a portion connecting the active portion and the upper surface electrode, and
the plating layer is formed on a portion, which overlaps with the active hole end portion, of the upper surface electrode.

6. The semiconductor device according to claim 5, wherein
the semiconductor substrate has:
a drift region of a first conductivity type provided in the active portion; and
a well region of a second conductivity type provided enclosing the active portion in a top view,
the first contact hole includes a well hole end portion, which is closest to the first end side, of a portion connecting the well region and the upper surface electrode, and
the plating layer is formed on a portion, which overlaps with the well hole end portion, of the upper surface electrode.

7. The semiconductor device according to claim 1, wherein
the semiconductor substrate has a trench portion provided from the upper surface into the semiconductor substrate and having a longitudinal length in a first direction on the upper surface, and
the first outer hole end portion is an end portion of the first contact hole in the first direction.

8. The semiconductor device according to claim 2, wherein
the semiconductor substrate has a trench portion provided from the upper surface into the semiconductor substrate and having a longitudinal length in a first direction on the upper surface, and
the first outer hole end portion is an end portion of the first contact hole in the first direction.

9. The semiconductor device according to claim 5, wherein
the semiconductor substrate has a trench portion provided from the upper surface into the semiconductor substrate and having a longitudinal length in a first direction on the upper surface, and
the first outer hole end portion is an end portion of the first contact hole in the first direction.

10. The semiconductor device according to claim 2, wherein
the semiconductor substrate has a trench portion provided from the upper surface into the semiconductor substrate and having a longitudinal length in a first direction on the upper surface, and
the outer protection portion is provided between the first outer hole end portion and the first end side in the first direction.

11. The semiconductor device according to claim 3, wherein
the semiconductor substrate has:
an active portion in which a semiconductor element is formed;
a trench portion provided from the upper surface into the semiconductor substrate and having a longitudinal length in a first direction on the upper surface;
a drift region of a first conductivity type provided in the active portion;
a base region of a second conductivity type provided between the drift region and the upper surface and being in contact with the trench portion; and
an accumulation region of the first conductivity type provided between the drift region and the base region and having a higher concentration than the drift region, and
in the first direction, the inner protection end portion is provided between the accumulation region and the first end side.

12. The semiconductor device according to claim 1, wherein
the semiconductor substrate has a plurality of trench portions lined up in a second direction on the upper surface,
each of the plurality of trench portions is provided from the upper surface into the semiconductor substrate and has a longitudinal length in a first direction on the upper surface, and
the first outer hole end portion is an end portion of the first contact hole in the second direction.

13. The semiconductor device according to claim 2, wherein
the semiconductor substrate has a plurality of trench portions lined up in a second direction on the upper surface,
each of the plurality of trench portions is provided from the upper surface into the semiconductor substrate and has a longitudinal length in a first direction on the upper surface, and
the first outer hole end portion is an end portion of the first contact hole in the second direction.

14. The semiconductor device according to claim 5, wherein
the semiconductor substrate has a plurality of trench portions lined up in a second direction on the upper surface,
each of the plurality of trench portions is provided from the upper surface into the semiconductor substrate and has a longitudinal length in a first direction on the upper surface, and
the first outer hole end portion is an end portion of the first contact hole in the second direction.

15. The semiconductor device according to claim 3, wherein
the semiconductor substrate has:
an active portion in which a semiconductor element is formed;
a plurality of trench portions lined up in a second direction on the upper surface;
a drift region of a first conductivity type provided in the active portion;
a base region of a second conductivity type provided between the drift region and the upper surface; and
an accumulation region of the first conductivity type provided between the drift region and the base region and having a higher concentration than the drift region,
each of the plurality of trench portions is provided from the upper surface into the semiconductor substrate and has a longitudinal length in a first direction on the upper surface, and
in the second direction, the inner protection end portion is provided between the accumulation region and the first end side.

16. The semiconductor device according to claim 3, wherein
the semiconductor substrate has:
an active portion in which a semiconductor element is formed;
a plurality of trench portions lined up in a second direction on the upper surface;
a drift region of a first conductivity type provided in the active portion;
a base region of a second conductivity type provided between the drift region and the upper surface and being in contact with the trench portion; and
a contact region of the second conductivity type provided between the upper surface and the base region, connected to the upper surface electrode, and having a higher concentration than the base region,
each of the plurality of trench portions is provided from the upper surface into the semiconductor substrate and has a longitudinal length in a first direction on the upper surface, and
in the second direction, the inner protection end portion is provided between the contact region and the first end side.

17. The semiconductor device according to claim 1, wherein
the semiconductor substrate further has a second end side and a third end side in a top view,
the first contact hole includes a second outer hole end portion closest to the second end side and a third outer hole end portion closest to the third end side, and
the plating layer is formed on a portion, which overlaps with the second outer hole end portion, of the upper surface electrode and on a portion, which overlaps with the third outer hole end portion, of the upper surface electrode.

18. The semiconductor device according to claim 2, wherein
the semiconductor substrate further has a second end side and a third end side in a top view,
the first contact hole includes a second outer hole end portion closest to the second end side and a third outer hole end portion closest to the third end side, and
the plating layer is formed on a portion, which overlaps with the second outer hole end portion, of the upper surface electrode and on a portion, which overlaps with the third outer hole end portion, of the upper surface electrode.

19. The semiconductor device according to claim 5, wherein
the semiconductor substrate further has a second end side and a third end side in a top view,
the first contact hole includes a second outer hole end portion closest to the second end side and a third outer hole end portion closest to the third end side, and
the plating layer is formed on a portion, which overlaps with the second outer hole end portion, of the upper surface electrode and on a portion, which overlaps with the third outer hole end portion, of the upper surface electrode.

20. The semiconductor device according to claim 1, wherein
the plating layer contains at least one of nickel or copper.
